(19) United States
(12) Patent Application Publication
(10) Pub. No.: US 2026/0204326 A1
(43) Pub. Date: Jul. 16, 2026

(54) MEMORY DEVICE AND CONTROL METHOD THEREOF

(71) Applicant: MACRONIX International Co., Ltd., Hsinchu (TW)

(72) Inventors: You-Liang Chou, Taichung City (TW); Chun-Chang Lu, Hsinchu City (TW); Wen-Che Tsai, Hualien City (TW)

(73) Assignee: MACRONIX International Co., Ltd., Hsinchu (TW)

(21) Appl. No.: 19/023,284

(22) Filed: Jan. 16, 2025

(51) Int. Cl. G11C 16/34; G11C 16/10

(52) U.S. Cl. CPC G11C 16/3404; G11C 16/102

(57) ABSTRACT

A memory device and a control method thereof are provided. The memory device may be a three-dimensional NAND flash memory with high capacity and high performance. The memory device includes a memory array and a memory controller. The memory array includes a plurality of memory pages. The memory controller is configured to control the memory array. In a program operation of a current memory page, the memory controller applies a plurality of compensation voltages to a plurality of low threshold parts of a plurality of states of a threshold voltage distribution of a previous memory page through a previous word line, and memory controller further applies a pass voltage to the plurality of states of the threshold voltage distribution of the previous memory page and a plurality of corresponding states of a threshold voltage distribution of the current memory page through the previous word line and a current word line.

### BACKGROUND

### Technical Field

The present invention relates to a control technology applied to a memory device (for example, NAND flash memory (NAND flash)), and in particular, to a memory device and a control method thereof.

### Description of Related Art

High-capacity and high-performance integrated circuit memories including three-dimensional (3D) NAND flash memory are continuing to develop, hoping to use three-dimensional stacking technology and triple-level cells, TLC) to reduce the size of memory cells and increase data storage density.

For a general memory device, when the memory controller performs incremental step pulse programming (ISPP) on the current memory page, a plurality of program voltages applied to a plurality of states of a threshold voltage distribution of a current memory page may generate additional program noise interference and program pattern effect on a plurality of states of a threshold voltage distribution of a previous memory page, so it is easy to cause data errors in the data stored in a plurality of memory cells of the previous memory page.

### SUMMARY

The invention provides a memory device and a control method thereof, which can provide reliable data storage function.

The memory device of the present invention includes a memory array and a memory controller. The memory controller is coupled to the memory array, and configured to control the memory array. In a program operation of a current memory page, the memory controller applies a plurality of compensation voltages to a plurality of low threshold parts of a plurality of states of a threshold voltage distribution of a previous memory page through a previous word line, and memory controller further applies a pass voltage to the plurality of states of the threshold voltage distribution of the previous memory page and a plurality of corresponding states of a threshold voltage distribution of the current memory page through the previous word line and a current word line.

The control method of the present invention is suitable for a memory device. The memory device includes a memory array. The memory array includes a plurality of memory pages. The control method includes the following steps: in a program operation of a current memory page, applying a plurality of compensation voltages to a plurality of low threshold parts of a plurality of states of a threshold voltage distribution of a previous memory page through a previous word line; and in the program operation of the current memory page, further applying a pass voltage to the plurality of states of the threshold voltage distribution of the previous memory page and a plurality of corresponding states of a threshold voltage distribution of the current memory page through the previous word line and a current word line.

Based on the above, the memory device and the control method thereof of the present invention may compensate the plurality of states in the threshold voltage distribution of the previous memory page during the program operation of the current memory page, so as to effectively reduce the impact of multiple states in the threshold voltage distribution of the previous memory page from fast charge loss (short-term retention), interference caused by additional program noise and program pattern effects.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of a memory device according to an embodiment of the invention.

FIG. 2 is a schematic diagram of the three-dimensional architecture of a memory array according to an embodiment of the invention.

FIG. 3 is a schematic diagram of threshold voltage distribution according to an embodiment of the invention.

FIG. 4 is a schematic diagram of a table of a programming relationship between a previous memory page and a current memory page according to an embodiment of the invention.

FIG. 5 is a schematic diagram of a control method according to an embodiment of the invention.

FIG. 6A is a schematic diagram of a voltage waveform of a word line according to an embodiment of the invention.

FIG. 6B and FIG. 6C are schematic diagrams of voltage waveform of a bit line according to an embodiment of the invention.

FIG. 7 is a schematic diagram of a compensated threshold voltage distribution according to an embodiment of the invention.

### DESCRIPTION OF THE EMBODIMENTS

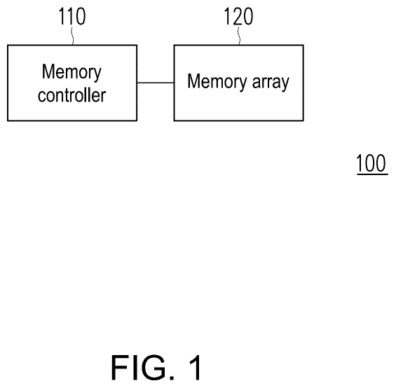

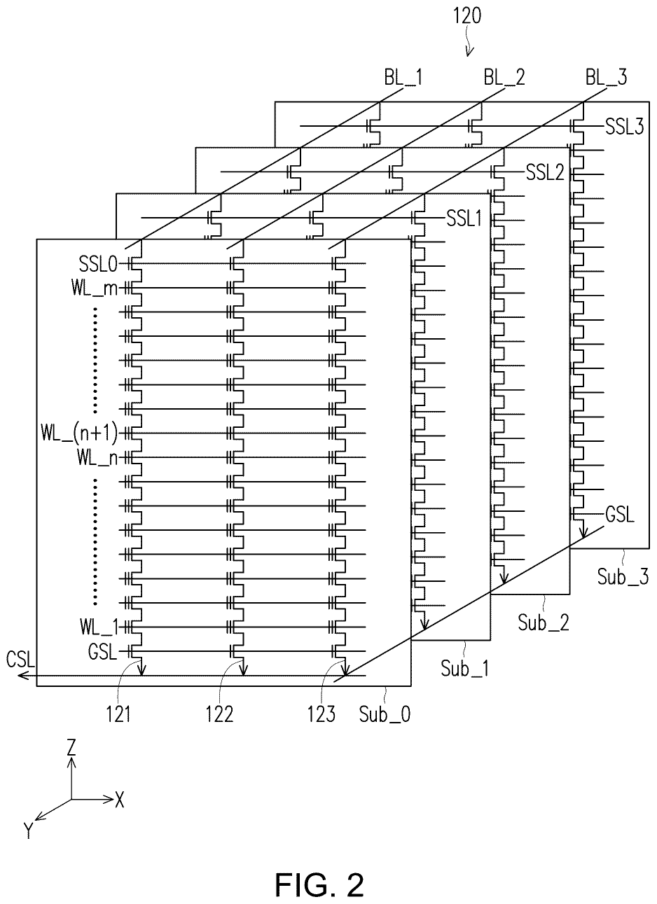

FIG. 1 is a schematic diagram of a memory device according to an embodiment of the invention. FIG. 2 is a schematic diagram of the three-dimensional architecture of a memory array according to an embodiment of the invention. Referring to FIG. 1 firstly, the memory device 100 includes a memory controller 110 and a memory array 120. The memory controller 110 is coupled to the memory array 120 and configured to control the memory array 120. In the embodiment, the memory device 100 may be a three-dimensional NAND memory device. The memory array 120 may include a plurality of memory cells, and the plurality of memory cells may be arranged in a three-dimensional manner.

Then, referring to FIG. 2, which presents an equivalent circuit example of a three-dimensional NAND memory in a three-dimensional manner. As shown in FIG. 2, in the XYZ coordinate system, the memory array 120 may be divided into four sub-blocks Sub_0~Sub_3, etc., and each sub-block may be operated independently. In this example, taking the sub-block Sub_0 as an example, the sub-block Sub_0 includes strings 121 to 123, where each of the strings 121 to 123 includes a plurality of memory cells connected in series along the Z orientation. Each of the plurality of memory cells on the strings 121 to 123 corresponds to one of a plurality of word lines WL_1 to WL_m, where the word lines WL_1 to WL_m may be respectively arranged on a layer in the parallel XY plane. The plurality of memory cells in the sub-blocks Sub_0~Sub_3 may be respectively coupled to a plurality of string select transistors of a plurality of string select lines SSL0 to SSL3, and the plurality of memory cells may be coupled to the corresponding ground respectively, and the plurality of memory cells may be respectively coupled to the ground select transistor coupled to the corresponding ground select line GSL.

In this example, the string select transistor and the ground select transistor are placed on opposite sides of the memory cell in the corresponding string. In the example of FIG. 2, a plurality of strings on the same plane (e.g. the plane defined by X orientation and Z orientation) coupled to the same string selection line may be defined as a sub-block.

In this example, each string is coupled to a corresponding one of a plurality of bit lines BL_1 to BL_3 through a corresponding string select transistor on the corresponding string select line. Moreover, strings in the same column along the Y orientation of different sub-blocks may be coupled to the corresponding same bit line. The string select line SSL may be formed as a wire or layer above the top of the topmost word line layer of the memory array. Each string may be coupled to the same common source line CSL through a corresponding ground select transistor on the ground select line GSL. The ground select line GSL may be formed as a conductor or layer below the bottom of the bottommost word line layer of the memory array. The common source line CSL may form a conductive layer above the substrate of the three-dimensional memory.

In this example, the plurality of string select lines in memory array 120 may be on the same conductive layer but divided into the plurality of separate stripes. Moreover, each separate strip on the same conductive layer may independently control the operation of the corresponding sub-block in the memory array 120 of the three-dimensional NAND memory.

In one example, the plurality of memory cells coupled to the same word line or word line layer in the sub-block may be defined as a memory page (in a single level cell (SLC) mode). In another example, the plurality of memory cells coupled to the same word line or word line layer may be defined as three memory pages (in a triple level cell (TLC) mode). In the triple level cell model, the three memory pages may include a high page, a middle page and a low page. Moreover, the plurality of memory cells on the same word line may be applied with the same voltage. The same word line may be coupled to a corresponding driver circuit, such as an X decoder (or scan driver).

In one example, one or more dummy lines or layers (not shown) may be disposed between the string select line and the topmost word line layer of string, and/or the ground select line GSL and the bottommost word line of string layer. In another embodiment, one or more virtual lines or layers (not shown) may be disposed in the middle portion of the string.

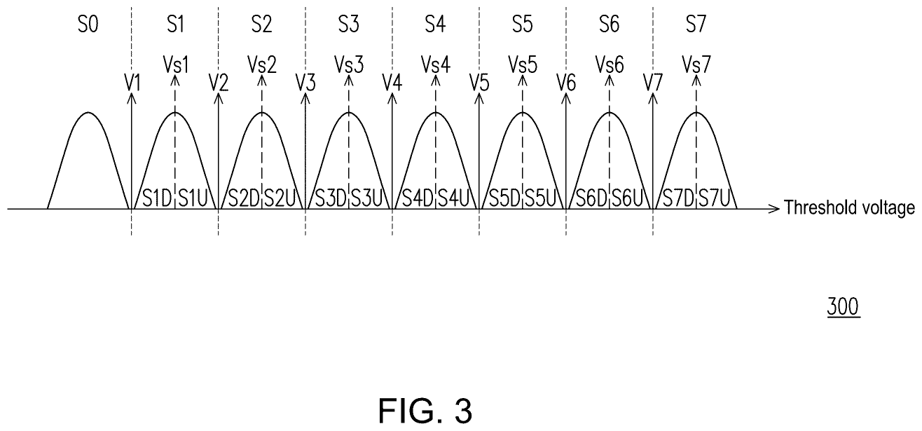

FIG. 3 is a schematic diagram of threshold voltage distribution according to an embodiment of the invention. Referring to FIG. 1 to FIG. 3, in the embodiment, the memory controller 110 may sequentially program a plurality of memory pages coupled to word line WL_m to word line WL_1 starting from the side close to the bit line BL_1. The following description takes two memory pages coupling the word line WL_(n+1) and the word line WL_n as an example, where n is between 1 and m. After the memory controller 110 completes encoding a previous memory page coupled to the word line WL_(n+1), the memory controller 110 may then encode a current memory page coupled to the word line WL_n.

The description takes a triple level cell (TLC) mode as an example, but the invention is not limited thereto. The memory device 100 of the present invention may also be applied to other multi-level cell model. In the embodiment, after the previous memory page is encoded, the previous memory page may have a threshold voltage distribution 300 as shown in FIG. 3. The threshold voltage distribution 300 of the previous memory page may be divided into a plurality of states S0 to S7 through a plurality of voltages V1 to V7, where the state S0 is an erase state.

In this embodiment, before encoding the current memory page coupled to the word line WL_n, the memory controller 110 may apply seven read voltages Vs1 to Vs7 with specific voltage levels through the word line WL_(n+1) to the threshold voltage distribution 300 of the previous memory page to distinguish a low threshold part and a high threshold part of each states S1 to S7, and read the stored data contents of a plurality of low threshold parts S1D to S7D and a plurality of high threshold parts S1U to S7U of the states S1 to S7 by reading the voltages Vs1 to Vs7.

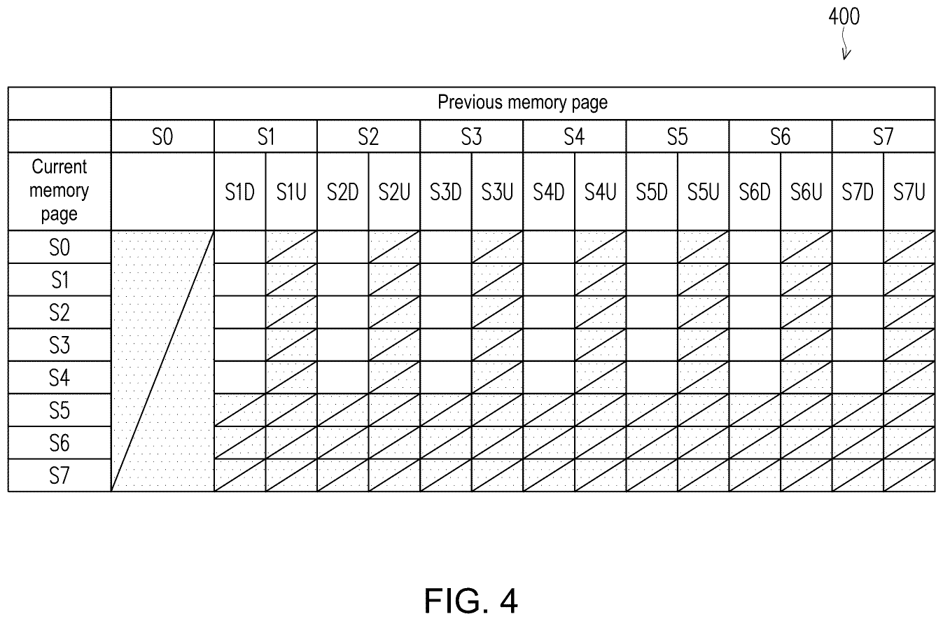

FIG. 4 is a schematic diagram of a table of a control method of a memory device according to an embodiment of the invention. Referring to FIG. 1 to FIG. 4, continuing the implementation example of FIG. 3, during a program operation of the current memory page by the memory controller 110, the memory controller 110 may compensate a plurality of states S1 to S7 of the threshold voltage distribution 300 of the previous memory page to effectively reduce some factors to widen the threshold voltage distribution like fast charge loss (short-term retention), the interference caused by additional program noise and the impact of program pattern effect. It should be noted that, the program operation refers to a voltage application operation of incremental step pulse programming (ISPP) on the current memory page.

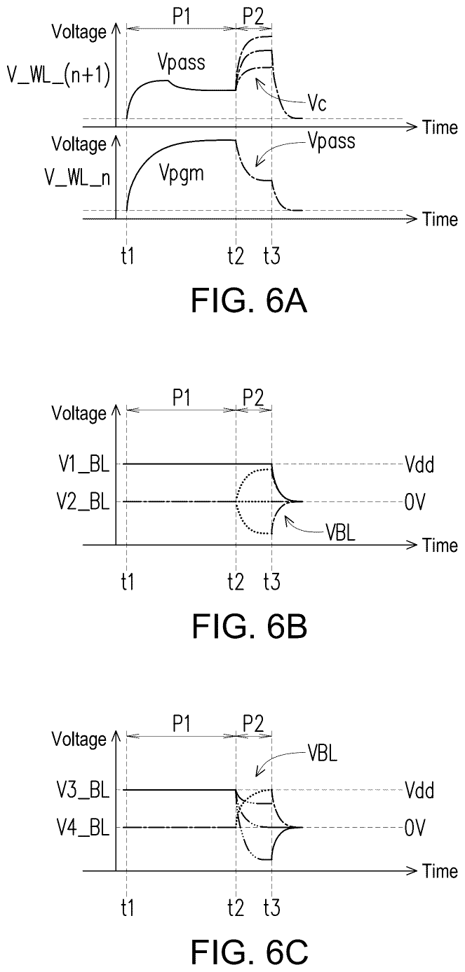

As shown in FIG. 4, FIG. 4 is a schematic diagram of a programming relationship table 400, and the memory controller 110 may determine whether to compensate the low threshold part S1D to S7D of the states S1 to S7 of the threshold voltage distribution 300 of the previous memory page according to the programming relationship table 400. As shown in FIG. 4, the state S0 of the threshold voltage distribution of the current memory page is the erased state and the cells of state S0 are not involved in the ISPP, but the memory controller 110 still compensates the low threshold parts S1D to S7D of the states S1 to S7 of the threshold voltage distribution 300 of the previous memory page. The compensation operation can be embedded in the phase P2 for bit line voltage waveforms V2_BL and V3_BL as shown in FIGS. 6B and 6C when the memory controller 110 is performing a program operation of ISPP on the state S1 to S7.

When the memory controller 110 is performing the program operation of ISPP on the states S1 to S4 of the threshold voltage distribution of the current memory page, the memory controller 110 may respectively compensate the low threshold parts S1D to S7D of the states S1 to S7 of the threshold voltage distribution 300 of the previous memory page (represented by the block without slash). Furthermore, the memory controller 110 may not compensate the high threshold parts S1U to S7U of states S1 to S7 of the threshold voltage distribution 300 of the previous memory page (represented by the block with slash).

Moreover, during the process of the program operation of ISPP for the states S5 to of the threshold voltage distribution of the current memory page through the current word line WL_n, the threshold voltage distribution states S0 to S7 of the previous memory page may be subject to strong interference effects when the states S5 to S7 of the current memory page are programmed. Therefore, when the memory controller 110 performs the program operation of ISPP on the states S5 to S7 of the threshold voltage distribution of the current memory page, the memory controller 110 also does not compensate the states S0 to S7 of the threshold voltage distribution 300 of the previous memory page (represented by the block with slash).

However, the states without compensation are not limited to the example embodiment of FIG. 4. In one embodiment, during the program operation of ISPP of the states S1 to S6 threshold voltage distribution of the current memory page, the memory controller 110 may also compensate the low threshold parts S1D to S7D of the states S1 to S7 of the threshold voltage distribution 300 of the previous memory page, respectively. Moreover, during the program operation of ISPP of the state S0 and state S7 of the threshold voltage distribution of the current memory page, the memory controller 110 may does not compensate the low threshold parts S1D to S7D of the states S1 to S7 of the threshold voltage distribution 300 of the previous memory page.

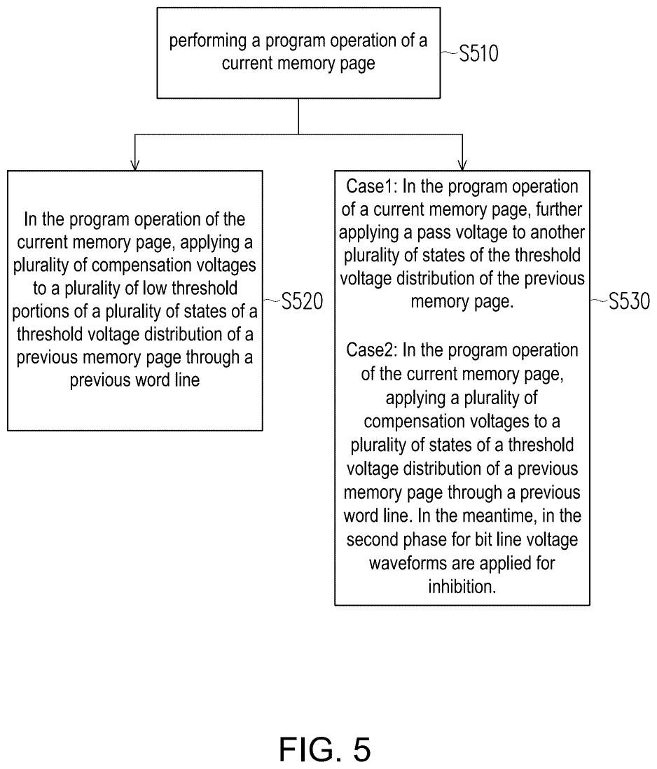

FIG. 5 is a schematic diagram of a programming relationship between a previous memory page and a current memory page according to an embodiment of the invention which is a second phase (P2 indicated in FIG. 6A) of the ISPP of the current page. Referring to FIG. 1 to FIG. 5, in the embodiment, during the program operation of ISPP of the current memory page, the memory controller 110 may perform the following steps S510 to S530. In step S510, the memory controller 110 performs the program operation of the current memory page. In step S520, in the program operation (the second phase P2) of the current memory page, the memory controller 110 applies a plurality of compensation voltages to the low threshold value parts of the states of the threshold voltage distribution 300 of the previous memory page through the previous word line WL_(n+1). In this regard, for example, as shown in FIG. 4, during the program operation of ISPP of the states S1 to S4 of the threshold voltage distribution of the current memory page, the memory controller 110 applies the compensation voltages to the low threshold value parts S1D to S7D of the states S1 to S7 of the threshold voltage distribution 300 of the previous memory page through the previous word line WL_(n+1).

In step S530, during the program operation of the current memory page in the second phase, the memory controller 110 also applies a pass voltage to the states of threshold voltage distribution 300 of the corresponding previous memory page through the pervious word line WL_(n+1) (P2 but not shown in FIG. 6A). In this regard, for example, as shown in FIG. 4, during the program operation of ISPP of states S5 to S7 of the threshold voltage distribution of the current memory page, the memory controller 110 may apply the pass voltage to the states S0 to S7 of the threshold voltage distribution 300 of the previous memory page through the previous word line WL_(n+1) in the second phase (P2 but not shown in FIG. 6A). Besides, the memory controller 110 may just apply program voltages to states S1 to S7 of the threshold voltage distribution of the current memory page.

There is another example in step S530. In the program operation (the second phase P2) of the current memory page, the memory controller 110 applies a plurality of compensation voltages (shown in FIG. 6A) to the states of the threshold voltage distribution 300 of the previous memory page through the previous word line WL_(n+1). In the meantime, in the second phase P2 for bit line voltage waveforms V1_BL and V4_BL are applied for inhibition (shown in FIGS. 6B, 6C).

Moreover, in the embodiment, the memory controller 110 further applies the pass voltage to the high threshold parts of the states of the threshold voltage distribution 300 of the previous memory page through the previous word line WL_(n+1) in the second phase (P2 not shown in FIG. 6A). In this regard, for example, as shown in FIG. 4, during the program operation of ISPP of the states S1 to S7 of the threshold voltage distribution of the current memory page, the memory controller 110 may apply the pass voltage to the high threshold parts S1U to S7U of the states S1~S7 of the threshold voltage distribution 300 of the previous memory page through the previous word line WL_(n+1) in the second phase (P2 not shown in FIG. 6A).

In addition, during the process of the memory controller 110 performing the program operation of ISPP on the threshold voltage distribution of the current memory page, if the states of the threshold voltage distribution of the current memory page indicate that a program voltage needs to be applied, but the states of the threshold voltage distribution 300 of the previous memory page indicate that no compensation needs to be applied, the memory controller 110 provides a voltage of 0 volts to bit line during the first phase (P1 indicated in FIG. 6A). Moreover, the memory controller 110 may switch to provide the inhibit voltage to the bit line during the second phase (P2 indicated in FIG. 6A) to apply the inhibit voltage to the states of the threshold voltage distribution 300 of the previous memory page.

Next, refer to FIG. 6A, FIG. 6A is a schematic diagram of a voltage waveform of a word line according to an embodiment of the invention. A voltage waveform V_WL_(n+1) of the previous word line WL_(n+1) and a voltage waveform V_WL_n of the current word line WL_n may be shown in FIG. 6A. In the embodiment, when the memory controller 110 performs the program operation of ISPP on the threshold voltage distribution of the current memory page, during the program period P1 from time t1 to time t2 (first phase), the memory controller 110 may apply a program voltage Vpgm to the states S1 to S7 of the threshold voltage distribution of the current memory page through the current word line WL_n, where the program voltage Vpgm may be determined by one of the current program states S1 to S7 of the threshold voltage distribution of the current memory page. Moreover, during the program period P1, the memory controller 110 may apply a pass voltage Vpass to the states S0 to S7 of the previous memory page through the previous word line WL_(n+1).

Then, during a compensation period P2 from time t2 to time t3 (second phase), when the program operation of ISPP of states S1 to S4 of the threshold voltage distribution of the current memory page is in the first phase (from time t1 to time t2), the memory controller 110 may compensate the low threshold parts S1D to S7D of the states S1 to S7 of the threshold voltage distribution 300 of the previous memory page that need to be compensated. In this regard, the memory controller 110 may apply the compensation voltage Vc through the previous word line WL_(n+1) to the low threshold value parts S1D to S7D of the states S1 to S7 of the threshold voltage distribution 300 of the previous memory page. Moreover, in the compensated period P2, the memory controller 110 may apply the pass voltage Vpass to the states S0 to S7 of the current memory page through the current word line WL_n.

In this embodiment, the compensation voltage Vc may be determined by the corresponding one of the states S0 to S7 of the threshold voltage distribution 300 of the previous memory page. In this embodiment, the compensated voltage Vc is higher than the pass voltage Vpass.

FIG. 6B and FIG. 6C are schematic diagrams of voltage waveform of a bit line according to an embodiment of the invention. In one embodiment, the memory controller 110 may also apply different bit line voltages on the bit line BL_1 by modulating the bit line voltages. Specifically, referring to FIG. 6B, during the process of the memory controller 110 performing the program operation of ISPP on the threshold voltage distribution of the current memory page, if the states of the threshold voltage distribution of the current memory page indicate that no program operation (inhibition) needs to be applied, and the states of the threshold voltage distribution 300 of the previous memory page indicate that no compensation needs to be applied, then as shown as the bit line voltage waveform V1_BL, the memory controller 110 provides an inhibit voltage Vdd to the bit line BL_1 during the program period P1, to apply the inhibit voltage Vdd to the states of the threshold voltage distribution of the current memory page. Furthermore, the memory controller 110 continues to provide the inhibit voltage Vdd to the bit line BL_1 during the compensation period P2 to apply the inhibit voltage Vdd to the states of the threshold voltage distribution 300 of the previous memory page. Meanwhile, in one embodiment, the compensation voltage may still be applied to the previous word line WL_(n+1), but the states of the threshold voltage distribution 300 of the previous memory page will be inhibited because the inhibit voltage Vdd be applied to the bit line BL_1.

During the process of the memory controller 110 performing the program operation of ISPP on the threshold voltage distribution of the current memory page, if the states of the threshold voltage distribution of the current memory page indicate that the program voltage needs to be applied, and the states of the threshold voltage distribution 300 of the previous memory page indicate that the compensation voltage needs to be applied, as shown in the bit line voltage waveform V2_BL, the memory controller 110 provides the voltage of 0 volts to bit line BL_1 during the program period P1. Moreover, the memory controller 110 may switch to provide the bit line voltage VBL to the bit line BL_1 during the compensation period P2. In the embodiment, the bit line voltage VBL is determined by the corresponding states of the threshold voltage distribution of the previous memory page.

Next, referring to FIG. 6C, during the process of the memory controller 110 performing the program operation of ISPP on the threshold voltage distribution of the current memory page, if the states of the threshold voltage distribution of the current memory page indicate that no program needs to be applied, but the states of the threshold voltage distribution 300 of the previous memory page indicate that a compensation voltage needs to be applied, as shown in the bit line voltage waveform V3_BL, the memory controller 110 provides the inhibit voltage Vdd to the bit line BL_1 during the program period P1, to apply the inhibit voltage Vdd to the states of the threshold voltage distribution of the current memory page. Moreover, the memory controller 110 may switch to provide the bit line voltage VBL to the bit line BL_1 during the compensation period P2.

During the process of the memory controller 110 performing the program operation of ISPP on the threshold voltage distribution of the current memory page, if the states of the threshold voltage distribution of the current memory page indicate that a program voltage needs to be applied, but the states of the threshold voltage distribution 300 of the previous memory page indicate that no compensation needs to be applied, as shown in the bit line voltage waveform V4_BL, the memory controller 110 provides a voltage of 0 volts to bit line BL_1 during the program period P1. Moreover, the memory controller 110 may switch to provide the inhibit voltage Vdd to the bit line BL_1 during the compensation period P2 to apply the inhibit voltage Vdd to the states of the threshold voltage distribution 300 of the previous memory page.

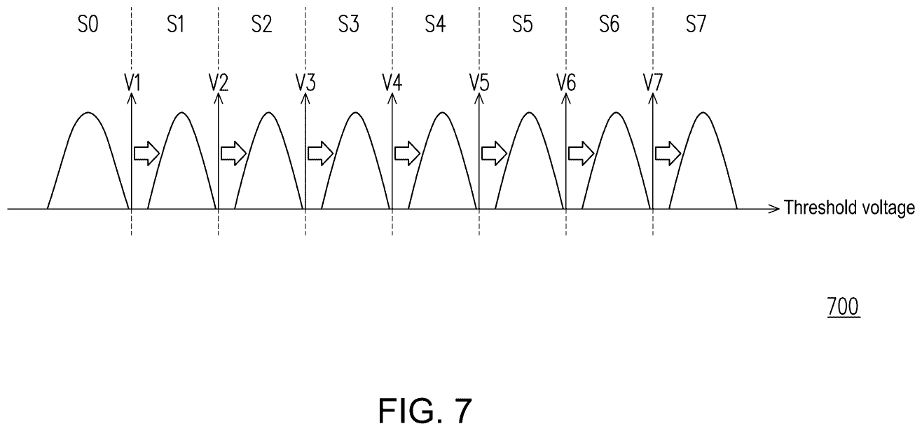

FIG. 7 is a schematic diagram of a compensated threshold voltage distribution according to an embodiment of the invention. Referring to FIG. 7, after the compensation in the above embodiment, the previous memory page may have a threshold voltage distribution 700 as shown in FIG. 7. As shown in FIG. 7, the voltage distribution boundaries of the low threshold parts of states S1 to S7 of the threshold voltage distribution 700 of the previous memory page may be shifted toward the voltage distribution boundaries of the high threshold parts. Thus, during the program operation of ISPP of the threshold voltage distribution of the current memory page, the entire states S1 to S7 of the threshold voltage distribution 700 of the previous memory page may be less affected by interference and program pattern effects, thereby effectively maintaining the fidelity of the stored data in the previous memory page.

In summary, the memory device and the control method thereof of the invention may apply the corresponding compensation voltage to the threshold voltage of the previous memory page through the previous word line during the program operation of the current memory page, and may effectively reduce the impact of the entire states in the threshold voltage distribution of the previous memory page from interference caused by additional program noise and program pattern effects.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a memory array, comprising a plurality of memory pages; and
a memory controller, coupled to the memory array, and configured to control the memory array,
wherein in a program operation of a current memory page, the memory controller applies a plurality of compensation voltages to a plurality of low threshold parts of a plurality of states of a threshold voltage distribution of a previous memory page through a previous word line, and memory controller further applies a pass voltage to the plurality of states of the threshold voltage distribution of the previous memory page and a plurality of corresponding states of a threshold voltage distribution of the current memory page through the previous word line and a current word line.

2. The memory device according to claim 1, wherein the memory controller further applies the pass voltage to a plurality of high threshold parts of the plurality of states of the threshold voltage distribution of the previous memory page through the previous word line.

3. The memory device according to claim 1, wherein corresponding to the low threshold parts of the states of the threshold voltage distribution of the previous memory page, the memory controller applies the pass voltage to the plurality of states of the threshold voltage distribution of the current memory page through the current word line.

4. The memory device according to claim 1, wherein the plurality of compensation voltages are determined by the plurality of states of the threshold voltage distribution of the previous memory page.

5. The memory device according to claim 1, wherein the compensation voltage is higher than the pass voltage.

6. The memory device according to claim 1, wherein in the program operation of the current memory page, the memory controller further applies a plurality of word line voltages to the plurality of states of the threshold voltage distribution of the previous memory page by modulating a plurality of bit line voltages.

7. The memory device according to claim 6, wherein in the program operation of the current memory page, the memory controller further applies an inhibit voltage to the plurality of states of the threshold voltage distribution of the previous memory page by modulating a plurality of bit line voltages.

8. The memory device according to claim 7, wherein the plurality of bit line voltages is determined by the plurality of states of the threshold voltage distribution of the previous memory page.

9. The memory device according to claim 1, wherein the plurality of states comprises an erase state.

10. A control method of a memory device, wherein the memory device comprises a memory array, and the comprises a plurality of memory pages, wherein the control method comprises:
in a program operation of a current memory page, applying a plurality of compensation voltages to a plurality of low threshold parts of a plurality of states of a threshold voltage distribution of a previous memory page through a previous word line; and
in the program operation of the current memory page, further applying a pass voltage to the plurality of states of the threshold voltage distribution of the previous memory page and a plurality of corresponding states of a threshold voltage distribution of the current memory page through the previous word line and a current word line.

11. The control method according to claim 10, further comprises:
in the program operation of the current memory page, further applying the pass voltage to a plurality of high threshold parts of the plurality of states of the threshold voltage distribution of the previous memory page through the previous word line.

12. The control method according to claim 10, further comprises:
corresponding to the low threshold parts of the states of the threshold voltage distribution of the previous memory page, applying the pass voltage to the plurality of states of the threshold voltage distribution of the current memory page through the current word line.

13. The control method according to claim 10, wherein the plurality of compensation voltages are determined by the plurality of states of the threshold voltage distribution of the previous memory page.

14. The control method according to claim 10, wherein the compensation voltage is higher than the pass voltage.

15. The control method according to claim 10, further comprising:
in the program operation of the current memory page, further applying a plurality of word line voltages to the plurality of states of the threshold voltage distribution of the previous memory page by modulating a plurality of bit line voltages.

16. The control method according to claim 15, further comprising:
in the program operation of the current memory page, further applying an inhibit voltage to the plurality of states of the threshold voltage distribution of the previous memory page by modulating a plurality of bit line voltages.

17. The control method according to claim 16, wherein the plurality of bit line voltages is determined by the plurality of states of the threshold voltage distribution of the previous memory page.

18. The control method according to claim 10, wherein the plurality of states comprises an erase state.
